(19) United States
(12) Patent Application Publication
(10) Pub. No.: US 2025/0107309 A1
(43) Pub. Date: Mar. 27, 2025

(54) TANDEM SOLAR CELL AND METHOD OF MANUFACTURING THE SAME

(71) Applicant: METAL INDUSTRIES RESEARCH & DEVELOPMENT CENTRE, KAOHSIUNG (TW)

(72) Inventors: Jia Hao LIN, Hualien County (TW); Wei-Chen TIEN, Chiayi City (TW); Yii-Der WU, KAOHSIUNG CITY (TW); Chang-Sin YE, Tainan City (TW); Cheng-Yuan HUNG, Kaohsiung City (TW)

(21) Appl. No.: 18/476,282

(22) Filed: Sep. 27, 2023

(51) Int. Cl. H10K 30/82; H10K 30/57; H10K 71/16

(52) U.S. Cl. CPC H10K 30/82; H10K 30/57; H10K 71/16

(57) ABSTRACT

A tandem solar cell and a method of manufacturing the same are provided. The tandem solar cell includes a bottom solar cell, a silicon suboxide thin film disposed over the bottom solar cell, a transparent conductive thin film disposed over the silicon suboxide thin film, and a top solar cell disposed on the transparent conductive thin film and series connected to the bottom solar cell. The silicon suboxide thin film has a refractive index of 2.0 to 3.5 for a visible light with a wavelength of 700 nm to 750 nm, and the transparent conductive thin film has a refractive index of 1.7 to 2.1 for the visible light with the wavelength of 700 nm to 750 nm. The tandem solar cell can achieve better optical matching and increase conversion efficiency.

### BACKGROUND

### Field of Invention

The disclosure relates to a tandem solar cell and a method of manufacturing the same, and more particularly, to the tandem solar cell with a middle layer and the method of manufacturing the same.

### Description of Related Art

Over the past few decades, silicon-based solar cells are always the mainstream in solar cell market as it holds a market share of about 95% currently. The silicon-based solar cells have advantage of high packaging efficiency, abundant materials, non-toxic elements and longer lifetime. In recent years, with discovery of components of passivated emitter rear cell (PERC) and tunnel oxide passivated contact (TOPCon), a conversion efficiency of the silicon-based solar cell keeps increasing.

Even though, the conversion efficiency of single solar cell still cannot satisfy requirement of application. Thus, two or more solar cells stacked to fabricate a tandem solar cell shows opportunity to increase the conversion efficiency. The tandem solar cell may be 4-terminal (4T) stacked structure or 2-terminal (2T) stacked structure. 4T tandem solar cell independently connects a top solar cell and a bottom solar cell, while 2T tandem solar cell connects the top solar cell and the bottom solar cell in series. It is no need for 4T tandem solar cell to consider current matching between the top solar cell and the bottom solar cell, thereby achieving more easily; while 2T tandem solar cell only need a transparent electrode, and thus it needs lower cost.

However, the 2T tandem solar cell needs a middle layer to connect the top solar cell and the bottom solar cell, thereby assuring electrons and holes recombine inside the cell. Thus, the middle layer needs great carrier transport property. The top solar cell should keep great ohmic contact with the bottom solar cell, but there is always a great difference in optical refractive index, which may cause optical current loss of the bottom solar cell. Thus, the middle layer should have a specific refractive index. Accordingly, optical matching of the middle layer is one of the key factors in the conversion efficiency of the 2T tandem solar cell.

Accordingly, there is a need to provide a tandem solar cell to achieve great optical matching, and even increasing the conversion efficiency of the solar cell.

### SUMMARY

An aspect of the disclosure is to provide a tandem solar cell, which includes a silicon suboxide thin film and a transparent conductive thin film with specific refractive indexes to increase the conversion efficiency of the solar cell.

Another aspect of the disclosure is to provide a method of manufacturing a tandem solar cell, which is used to manufacture the tandem solar cell of the above aspect.

According to the aspect, a tandem solar cell is provided. The tandem solar cell includes a bottom solar cell, a silicon suboxide thin film disposed over the bottom solar cell, a transparent conductive thin film disposed over the silicon suboxide thin film, and a top solar cell disposed on the transparent conductive thin film and series connected to the bottom solar cell. The silicon suboxide thin film has a refractive index of 2.0 to 3.5 for a visible light with a wavelength of 700 nm to 750 nm, and the transparent conductive thin film has a refractive index of 1.7 to 2.1 for the visible light with the wavelength of 700 nm to 750 nm. The top solar cell faces towards an incident light.

According to an embodiment of the present disclosure, the bottom solar cell is a silicon-based solar cell, and the top solar cell is a perovskite solar cell.

According to an embodiment of the present disclosure, a thickness of the silicon suboxide thin film is 10 nm to 50 nm, and a sheet resistance of the silicon suboxide thin film is 1.0×10⁻³Ω-cm to 1.0×10⁻²Ω-cm.

According to an embodiment of the present disclosure, an optical energy bandgap of the transparent conductive thin film is 3.5 eV to 4.9 eV.

According to an embodiment of the present disclosure, a thickness of the transparent conductive thin film is 15 nm to 45 nm, and a sheet resistance of the transparent conductive thin film is 1.0×10⁻⁴Ω-cm to 1.0×10⁻³Ω-cm.

According to an embodiment of the present disclosure, the transparent conductive thin film comprises gallium oxide, indium oxide, indium tin oxide, indium gallium oxide or combinations thereof.

According to an embodiment of the present disclosure, for the visible light with the wavelength of 700 nm to 750 nm, a refractive index of the bottom solar cell is greater than the refractive index of the silicon suboxide thin film, and the refractive index of the transparent conductive thin film is greater than a refractive index of the top solar cell.

According to an embodiment of the present disclosure, the bottom solar cell has a refractive index of 3.6 to 4.0 for the visible light with the wavelength of 700 nm to 750 nm.

According to an embodiment of the present disclosure, the top solar cell has a refractive index of 1.5 to 2.0 for the visible light with the wavelength of 700 nm to 750 nm.

Another aspect of the disclosure provides a method of manufacturing the tandem solar cell of the above aspect. The method includes forming a silicon suboxide thin film of the tandem solar cell by plasma enhanced chemical vapor deposition process; and forming a transparent conductive thin film of the tandem solar cell by plasma enhanced atomic layer deposition process.

According to an embodiment of the present disclosure, the plasma enhanced chemical vapor deposition process is performed by using a mixed gas of silane and nitrous oxide or a mixed gas of silane and carbon dioxide.

According to an embodiment of the present disclosure, the plasma enhanced atomic layer deposition process is performed by using at least one of trimethylgallium, trimethylindium and tetrakis (dimethylamino) tin.

According to an embodiment of the present disclosure, a plasma frequency of the plasma enhanced chemical vapor deposition process is 40 MHz to 60 MHz, and a plasma power of the plasma enhanced chemical vapor deposition process is 60 W to 300 W.

According to an embodiment of the present disclosure, a plasma frequency of the plasma enhanced atomic layer deposition process is 40 MHz to 60 MHz, and a plasma power of the plasma enhanced atomic layer deposition process is 100 W to 300 W.

Another aspect of the disclosure provides a tandem solar cell. The tandem solar cell includes a bottom solar cell, a middle layer disposed on the bottom solar cell, and a top solar cell disposed on the middle layer. The middle layer includes a silicon suboxide thin film and a transparent conductive thin film disposed over the silicon suboxide thin film. The silicon suboxide thin film has a refractive index of 2.0 to 3.5 for a visible light with a wavelength of 700 nm to 750 nm, and the refractive index of the silicon suboxide is lower than a refractive index for the visible light with the wavelength of 700 nm to 750 nm of the bottom solar cell. The transparent conductive thin film has a refractive index of 1.7 to 2.1 for the visible light with the wavelength of 700 nm to 750 nm. The top solar cell has a refractive index for the visible light with the wavelength of 700 nm to 750 nm lower than the refractive index of the transparent conductive thin film. The top solar cell faces towards an incident light.

According to an embodiment of the present disclosure, for the visible light with the wavelength of 700 nm to 750 nm, the refractive index of the silicon suboxide thin film is greater than the refractive index of the transparent conductive thin film.

According to an embodiment of the present disclosure, the bottom solar cell is passivated emitter rear cell (PERC) solar cell, tunnel oxide passivated contact (TOPCon) solar cell or heterojunction with intrinsic thin layer (HJT) solar cell.

According to an embodiment of the present disclosure, the top solar cell and the bottom solar cell is series connected.

According to an embodiment of the present disclosure, the bottom solar cell has a refractive index of 3.6 to 4.0 for the visible light with the wavelength of 700 nm to 750 nm, and the top solar cell has a refractive index of 1.5 to 2.0 for the visible light with the wavelength of 700 nm to 750 nm.

According to an embodiment of the present disclosure, a grain size of the silicon suboxide thin film is 2 nm to 30 nm.

Application of the tandem solar cell and the method of manufacturing the same can use the silicon suboxide thin film and the transparent conductive thin film with specific refractive indexes as the middle layer between the top solar cell and the bottom solar cell. Therefore, greater optical matching can be achieved, thereby increasing the conversion efficiency of the tandem solar cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a tandem solar cell according to some embodiments of the present disclosure.

FIG. 2A illustrates an analysis diagram of an extinction coefficient and the refractive index for the visible light with the wavelength of 700 nm of the silicon suboxide thin film formed with different mixed gas ratio according to Experiment example 1.

FIG. 2B illustrates an analysis diagram of grain size of the silicon suboxide thin film formed with different mixed gas ratio according to Experiment example 1.

FIG. 3A illustrates an analysis diagram of an extinction coefficient and the refractive index for the visible light with the wavelength of 700 nm of the transparent conductive thin film formed with different In/Ga ratio according to Experiment example 2.

FIG. 3B illustrates an analysis diagram of a sheet resistance of the transparent conductive thin film formed with different In/Ga ratio according to Experiment example 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range.

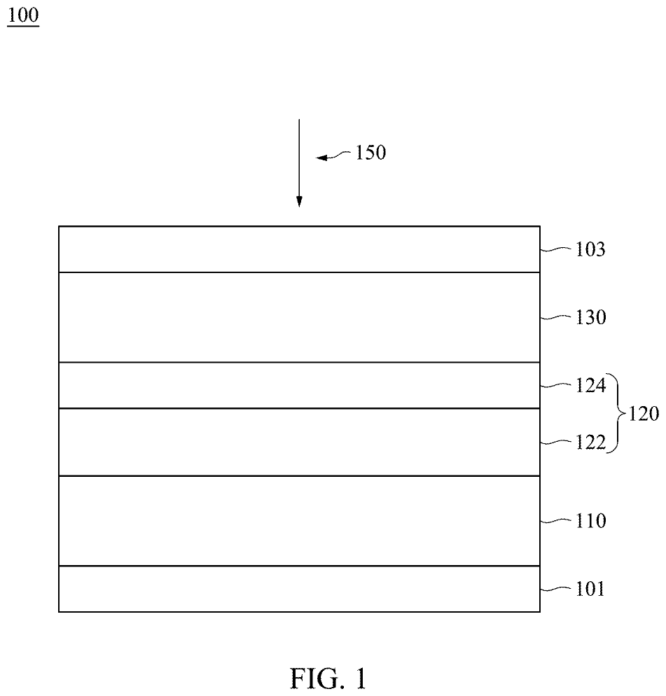

Referring to FIG. 1, FIG. 1 illustrates a schematic diagram of a tandem solar cell 100 according to some embodiments of the present disclosure. The tandem solar cell 100 includes a bottom solar cell 110, a middle layer 120 and a top solar cell 130. In some embodiments, the tandem solar cell 100 is a 2-terminal (2T) tandem solar cell; and thus, the tandem solar cell 100 further includes an electrode 101 and a transparent electrode 103 to conduct electric current transferred from optical energy.

In some embodiments, the bottom solar cell 110 is a silicon-based solar cell. In some examples, the bottom solar cell 110 may be a passivated emitter rear cell (PERC) solar cell, a tunnel oxide passivated contact (TOPCon) solar cell or a heterojunction with intrinsic thin layer (HJT) solar cell. In some embodiments, the bottom solar cell 110 has a refractive index of about 3.6 to about 4.0 for a visible light with a wavelength of 700 nm to 750 nm.

In some embodiments, the top solar cell 130 is a perovskite solar cell. In some embodiments, the top solar cell has a refractive index of about 1.5 to about 2.0 for the visible light with the wavelength of 700 nm to 750 nm. The top solar cell 130 and the bottom solar cell 110 are series connected.

The middle layer 120 includes a silicon suboxide thin film 122 and a transparent conductive thin film 124. In some embodiments, the silicon suboxide 122 has a refractive index of about 2.0 to about 3.5 for the visible light with the wavelength of 700 nm to 750 nm. In some embodiments, for the visible light with the wavelength of 700 nm to 750 nm, the refractive index of the silicon suboxide thin film 122 is smaller than the refractive index of the bottom solar cell 110; and thus, the bottom solar cell 110 and the top solar cell 130 can have better optical matching.

The silicon suboxide thin film 122 is composed of silicon suboxide (SiOₓ, in which x is smaller than 2) with p-type or n-type doping. In some embodiments, a thickness of the silicon suboxide thin film 122 is about 10 nm to about 50 nm, and a sheet resistance of the silicon suboxide thin film is 1.0×10⁻³Ω-cm to 1.0×10⁻²Ω-cm. The silicon suboxide thin film 122 with the thickness and/or the sheet resistance within the aforementioned range may have better carrier transport property.

In some embodiments, the silicon suboxide thin film 122 can be formed by plasma enhanced chemical vapor deposition (PECVD). In the aforementioned embodiments, a plasma frequency is about 40 MHz to about 60 MHz, such as 40.68 MHz, and a plasma power is about 60 W to about 300 W. The plasma frequency and the plasma power are controlled within the aforementioned range to ensure a better quality of the deposited thin film.

In some embodiments, the silicon suboxide thin film 122 can be formed by using a mixed gas of silane and nitrous oxide or a mixed gas of silane and carbon dioxide. In some embodiments, the aforesaid mixed gas can optionally include a small amount of hydrogen, for example, an amount ratio of silane/hydrogen is ½ to ¼. If amount of hydrogen is out of the aforementioned range, a deposition rate of the silicon suboxide thin film 122 may become slower. In the embodiments of the silicon suboxide thin film 122 is formed by the mixed gas of silane and carbon dioxide, based on volume of carbon dioxide as 100%, the volume of silane is about 15% to about 40%. Using the aforesaid volume ratio of the mixed gas to form the silicon suboxide thin film 122 can produce a silicon suboxide layer with the specific refractive index. If the PECVD is performed only with silane, the silicon suboxide may not be formed, and the refractive index of the produced thin film cannot meet the requirement.

After the PECVD, the silicon suboxide layer in amorphous condition can be transformed to the crystallized silicon suboxide thin film 122 by using high-temperature annealing. In some embodiments, a grain size of the silicon suboxide thin film 122 is about 2 nm to about 30 nm. The silicon suboxide thin film 122 has the grain size within the aforesaid range may have less lattice defect and suitable refractive index. In some embodiments, the aforementioned high-temperature annealing is performed with a temperature of about 700° C. to about 950° C. for about 1 hour to about 3 hours, thereby repairing the silicon suboxide thin film 122, and further increasing passivation property.

In some embodiments, the transparent conductive thin film 124 has a refractive index of about 1.7 to about 2.1 for the visible light with the wavelength of 700 nm to 750 nm. In some embodiments, for the visible light with the wavelength of 700 nm to 750 nm, the refractive index of the transparent conductive thin film 124 is greater than the refractive index of the top solar cell 130; and thus, the bottom solar cell 110 and the top solar cell 130 can have better optical matching. In some embodiments, for the visible light with the wavelength of 700 nm to 750 nm, the refractive index of the silicon suboxide thin film 122 is greater than the refractive index of the transparent conductive thin film 124; and thus, the middle layer 120 may have better optical matching. The conversion efficiency of the tandem solar cell 100 can be further increased by refractive index combination between the above layers.

In some embodiments, a thickness of the transparent conductive thin film 124 is about 15 nm to about 45 nm, and a sheet resistance of the transparent conductive thin film 124 is about 1.0×10⁻⁴Ω-cm to about 1.0×10⁻³Ω-cm. The transparent conductive thin film 124 with the thickness and/or the sheet resistance within the aforementioned range may have better carrier transport property.

In some embodiments, the transparent conductive thin film 124 can be formed plasma enhanced atomic layer deposition (PEALD). In the aforementioned embodiments, a plasma frequency is about 40 MHz to about 60 MHz, such as 40.68 MHz, and a plasma power is about 1000 W to about 300 W, thereby ensuring a better quality of the deposited thin film. Since the silicon suboxide thin film 122 formed by the PECVD may have an unevener surface, compared to using a traditional physical vapor deposition (PVD), the present disclosure uses PEALD to form the transparent conductive thin film 124, which may have better gap filling ability, better surface coverage and better uniformity. Moreover, compared to the traditional PVD, which may cause damage to the bottom solar cell 110 or other middle layers disposed on the bottom solar cell 110, the present disclosure uses PEALD to avoid causing damage by controlling the plasma.

In some embodiments, the transparent conductive thin film 124 includes gallium oxide, indium oxide, indium tin oxide (ITO), indium gallium oxide (IGO) or combinations thereof. The transparent conductive thin film 124 prefers to be indium gallium oxide because indium gallium oxide has greater optical energy gap to allow more light access into the bottom solar cell 110, thereby increasing the conversion efficiency of the tandem solar cell 100.

In some embodiments, when using PEALD to form the transparent conductive thin film 124, at least one of trimethylgallium, trimethylindium and tetrakis (dimethylamino) tin can be used as a precursor, and oxygen and inert gas in high concentration are inserted, in which the oxygen is used to form oxides, while the inert gas can be used to purge unreacted gases. It is understood that selection of the precursor depends on desired thin film material. In the embodiments of the transparent conductive thin film 124 is indium gallium oxide, trimethylgallium and trimethylindium are used as the precursors, in which a gas ratio is about 1:4 to about 1:34. With such gas ratio, oxygen vacancy of the thin film material can be controlled, and thus the obtained transparent conductive thin film 124 can have better conductivity (i.e. lower resistivity) and can have the suitable refractive index.

The top solar cell 130 is configured to face towards an incident direction of an incident light 150. The bottom solar cell 110 is disposed on the electrode 101, and the transparent electrode 103 is disposed on the top solar cell 130. In other words, the bottom solar cell 110 and the top solar cell 130 are disposed between the electrode 101 and the transparent electrode 103. Therefore, the incident light 150 enters the tandem solar cell 100 through the transparent electrode 103, the top solar cell 130, the middle layer 120, the bottom solar cell 110 and the electrode 101 sequentially.

The following examples are used to illustrate the application of the present disclosure, but those are not intended to limit the present disclosure. Any person skilled in the art can make various changes and modifications without departing from the spirit and scope of the present disclosure.

### Experiment Example 1

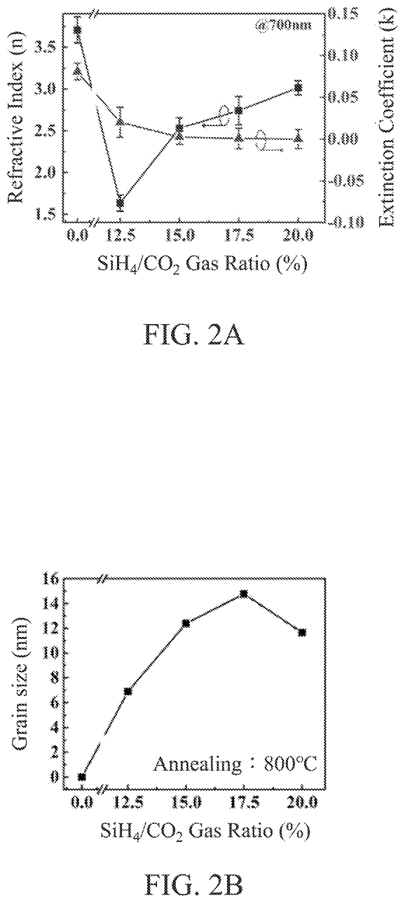

Experiment example 1 used the mixed gas with different ratio of silane and carbon dioxide to deposit the silicon suboxide layer, and performed the high-temperature annealing with the temperature of 800° C. for an hour to form the silicon suboxide thin film. The refractive index, extinction coefficient and the grain size of the obtained silicon suboxide thin film are detected. FIG. 2A is an analysis diagram of the extinction coefficient and the refractive index for the visible light with the wavelength of 700 nm of the silicon suboxide thin film formed with different mixed gas ratio; while FIG. 2B is an analysis diagram of the grain size of the silicon suboxide thin film formed with the different mixed gas ratio.

As shown in FIG. 2A, in the condition of not adding carbon dioxide, but only using silane to perform deposition, the obtained thin film had greater refractive index, which may not meet the requirement. After adding specific ratio of carbon dioxide, the silicon suboxide thin film was formed, and the refractive index could be in a range of requirement of application. Moreover, after adding the specific ratio of carbon dioxide, the extinction coefficient of the silicon suboxide thin film was decreased to avoid absorbing the incident light and further decreasing the conversion efficiency of the tandem solar cell.

As shown in FIG. 2B, after the high-temperature annealing, the amorphous silicon suboxide layer transformed to the crystallized silicon suboxide thin film, and the specific gas ratio allowed the silicon suboxide thin film have the suitable grain size, and may not grow to the grain with oversize and cause the defect.

### Experiment Example 2

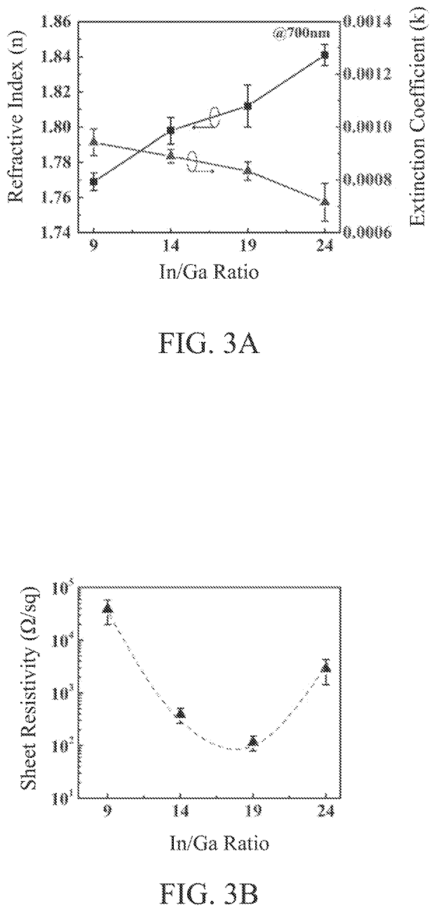

Experiment example 2 used trimethylindium and trimethylgallium with different ratio to form the transparent conductive thin film of indium gallium oxide. The refractive index, the extinction coefficient and the sheet resistance of the obtained transparent conductive thin film are detected. FIG. 3A is an analysis diagram of the extinction coefficient and the refractive index for the visible light with the wavelength of 700 nm of the transparent conductive thin film formed with different In/Ga ratio; while FIG. 3B is an analysis diagram of the sheet resistance of the transparent conductive thin film formed with different In/Ga ratio.

As shown in FIG. 3A, when In/Ga ratio is in a range of 9 to 24, the obtained transparent conductive thin film had the refractive index between 1.76 and 1.86, which met the requirement of application. The extinction coefficient of the transparent conductive thin film gradually decreased with increasing In/Ga ratio (within a range of 9 to 24), thereby decreasing absorption of the incident light to increase the conversion efficiency of the tandem solar cell.

As shown in FIG. 3B, when In/Ga ratio increased from 9 to 19, the sheet resistance of the transparent conductive thin film would decrease gradually. The reason is that when the In/Ga ratio is smaller, oxygen atoms are not enough for —OH bonding achieve saturation; therefore, the oxygen vacancy decreased and the resistance increased. When In/Ga ratio increased from 19 to 24, the sheet resistance of the transparent conductive thin film would increase gradually. As a result, In/Ga ratio could not be too great, or the sheet resistance would be too great and cannot meet requirement.

According to above embodiments, the present disclosure provides the tandem solar cell and the method of manufacturing the same, which uses the silicon suboxide thin film and the transparent conductive thin film with specific refractive indexes as the middle layer between the top solar cell and the bottom solar cell. Therefore, greater optical matching and great carrier transport property can be achieved, thereby increasing the conversion efficiency of the tandem solar cell.

It is understood that the aforementioned steps described in the embodiments of the disclosure can be combined or skipped, and the order thereof can be adjusted according actual requirements.

Although the disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims.

What is claimed is:

1. A tandem solar cell, comprising:
a bottom solar cell;
a silicon suboxide thin film, disposed over the bottom solar cell, wherein the silicon suboxide thin film has a refractive index of 2.0 to 3.5 for a visible light with a wavelength of 700 nm to 750 nm;
a transparent conductive thin film, disposed over the silicon suboxide thin film, wherein the transparent conductive thin film has a refractive index of 1.7 to 2.1 for the visible light with the wavelength of 700 nm to 750 nm; and
a top solar cell, disposed on the transparent conductive thin film and series connected to the bottom solar cell, wherein the top solar cell faces towards an incident light.

2. The tandem solar cell of claim 1, wherein the bottom solar cell is a silicon-based solar cell, and the top solar cell is a perovskite solar cell.

3. The tandem solar cell of claim 1, wherein a thickness of the silicon suboxide thin film is 10 nm to 50 nm, and a sheet resistance of the silicon suboxide thin film is 1.0×10⁻³Ω-cm to 1.0×10⁻²Ω-cm.

4. The tandem solar cell of claim 1, wherein an optical energy bandgap of the transparent conductive thin film is 3.5 eV to 4.9 eV.

5. The tandem solar cell of claim 1, wherein a thickness of the transparent conductive thin film is 15 nm to 45 nm, and a sheet resistance of the transparent conductive thin film is 1.0×10⁻⁴Ω-cm to 1.0×10⁻³Ω-cm.

6. The tandem solar cell of claim 1, wherein the transparent conductive thin film comprises gallium oxide, indium oxide, indium tin oxide, indium gallium oxide or combinations thereof.

7. The tandem solar cell of claim 1, wherein for the visible light with the wavelength of 700 nm to 750 nm, a refractive index of the bottom solar cell is greater than the refractive index of the silicon suboxide thin film, and the refractive index of the transparent conductive thin film is greater than a refractive index of the top solar cell.

8. The tandem solar cell of claim 1, wherein the bottom solar cell has a refractive index of 3.6 to 4.0 for the visible light with the wavelength of 700 nm to 750 nm.

9. The tandem solar cell of claim 1, wherein the top solar cell has a refractive index of 1.5 to 2.0 for the visible light with the wavelength of 700 nm to 750 nm.

10. A method of manufacturing the tandem solar cell of claim 1, wherein:
forming the silicon suboxide thin film of the tandem solar cell by plasma enhanced chemical vapor deposition process; and
forming the transparent conductive thin film of the tandem solar cell by plasma enhanced atomic layer deposition process.

11. The method of claim 10, wherein the plasma enhanced chemical vapor deposition process is performed by using a mixed gas of silane and nitrous oxide or a mixed gas of silane and carbon dioxide.

12. The method of claim 10, wherein the plasma enhanced atomic layer deposition process is performed by using at least one of trimethylgallium, trimethylindium and tetrakis (dimethylamino) tin.

13. The method of claim 10, wherein a plasma frequency of the plasma enhanced chemical vapor deposition process is 40 MHz to 60 MHz, and a plasma power of the plasma enhanced chemical vapor deposition process is 60 W to 300 W.

14. The method of claim 10, wherein a plasma frequency of the plasma enhanced atomic layer deposition process is 40 MHz to 60 MHz, and a plasma power of the plasma enhanced atomic layer deposition process is 100 W to 300 W.

15. A tandem solar cell, comprising:
a bottom solar cell;
a middle layer, disposed on the bottom solar cell, wherein the middle layer comprises:
a silicon suboxide thin film, wherein the silicon suboxide thin film has a refractive index of 2.0 to 3.5 for a visible light with a wavelength of 700 nm to 750 nm, and the refractive index of the silicon suboxide is lower than a refractive index for the visible light with the wavelength of 700 nm to 750 nm of the bottom solar cell; and
a transparent conductive thin film, disposed over the silicon suboxide thin film, wherein the transparent conductive thin film has a refractive index of 1.7 to 2.1 for the visible light with the wavelength of 700 nm to 750 nm; and
a top solar cell, disposed on the middle layer, wherein the top solar cell has a refractive index for the visible light with the wavelength of 700 nm to 750 nm lower than the refractive index of the transparent conductive thin film, and the top solar cell faces towards an incident light.

16. The tandem solar cell of claim 15, wherein for the visible light with the wavelength of 700 nm to 750 nm, the refractive index of the silicon suboxide thin film is greater than the refractive index of the transparent conductive thin film.

17. The tandem solar cell of claim 15, wherein the bottom solar cell is passivated emitter rear cell (PERC) solar cell, tunnel oxide passivated contact (TOPCon) solar cell or heterojunction with intrinsic thin layer (HJT) solar cell.

18. The tandem solar cell of claim 15, wherein the top solar cell and the bottom solar cell is series connected.

19. The tandem solar cell of claim 15, wherein the bottom solar cell has a refractive index of 3.6 to 4.0 for the visible light with the wavelength of 700 nm to 750 nm, and the top solar cell has a refractive index of 1.5 to 2.0 for the visible light with the wavelength of 700 nm to 750 nm.

20. The tandem solar cell of claim 15, wherein a grain size of the silicon suboxide thin film is 2 nm to 30 nm.
